(19) United States
(12) Patent Application Publication
(10) Pub. No.: US 2005/0168247 A1
(43) Pub. Date: Aug. 4, 2005

(54) Electrical transient sampling system using a regenerative gain-clamped fiber optic delay line

(75) Inventor: Craig S. Halvorson, Alameda, CA (US)

Correspondence Address: Michael C. Staggs;Attorney for Applicants, Lawrence Livermore National Laboratory, P.O. Box 808, L-703, Livermore, CA, 94551, US

(73) Assignee: The Regents of the University of California

(21) Appl. No.: 11/049,556

(22) Filed: Jan. 31, 2005

Related U.S. Application Data
(60) Provisional application No. 60/540,856, filed on Jan. 30, 2004.

(51) Int. Cl. H03K 5/00

(52) U.S. Cl. 327/91

(57) ABSTRACT

Transient signal measurements are bandwidth limited by present digitizer technology. If a transient signal can be stored in a gain-clamped regenerative delay line, such a signal can be regeneratively sampled, resulting in about an order of magnitude increase in measurement bandwidth. The approach involves converting electrical signals to optical signals with high fidelity, injecting such signals into a fiber-optic delay line, and then sampling injected signals repetitively, with signal generation provided by an erbium-doped gain-clamped fiber amplifier. Moreover, signal regeneration can be either steady state (i.e., amplification on each pass) or switched (i.e., amplification after signal levels have dropped significantly).

### RELATED APPLICATION

This application claims the benefit of U.S. Provisional Application No. 60/540,856, filed Jan. 30, 2004, entitled, “Electrical Transient Sampling System Using a Regenerative Fiber Optic Delay Line,” which is incorporated herein by this reference.

The United States Government has rights in this invention pursuant to Contract No. W-7405-ENG-48 between the United States Department of Energy and the University of California for the operation of Lawrence Livermore National Laboratory.

### BACKGROUND OF THE INVENTION

1. Field of the Invention

The present invention relates to a measurement system. More particularly, the present invention relates to an electrical transient sampling system that utilizes a gain-clamped optical fiber recirculation loop to substantially reproduce one or more transient signals.

2. Description of Related Art

The Nyquist sampling theorem states that an input signal must be sampled at a rate greater than twice the highest frequency component contained in the signal of interest. A beneficial sampling rate is often from about 4 to about 10 times the input bandwidth of the digital scope. However, when a true single-shot transient is to be analyzed, sampling such a signal can be problematic.

In general, there are two ways to get more samples on a single-shot transient waveform: 1) increase the sample rate, or 2) sample the waveform repetitively. The most obvious way to obtain more samples on the waveform is to increase the sample rate by using a faster analog-to-digital converter. However, the fastest available commercial sampling oscilloscopes have a resolution on the order of 35 ps, making such oscilloscopes somewhat undesirable for measuring single-shot transient signals of less than about 200 ps.

The second way to get more samples on a single-shot transient waveform is to reproduce the waveform and repetitively sample the single-shot transient signal waveform reproductions. Samples from different reproductions are combined to reconstruct the waveform. The reproduced displayed waveform is therefore made up of many acquisitions of the signal, similar to that of an analog scope.

Background information for reproducing a single-shot transient signal that includes a regenerative fiber loop, is described and claimed in U.S. Pat. No. 6,738,133 B1, entitled “Method and Apparatus For Measuring Single-Shot Transient Signals,” issued May 18, 2004 to Yin, including the following, “Methods, apparatus, and systems, including computer program products, implementing and using techniques for measuring multi-channel single-shot transient signals. A signal acquisition unit receives one or more single-shot pulses from a multi-channel source. An optical-fiber recirculating loop reproduces the one or more received single-shot optical pulses to form a first multi-channel pulse train for circulation in the recirculating loop, and a second multi-channel pulse train for display on a display device. The optical-fiber recirculating loop also optically amplifies the first circulating pulse train to compensate for signal losses and performs optical multi-channel noise filtration.”

Accordingly, a need exists for methods and apparatus that can measure a single-shot transient signal. The present invention is directed to such a need.

### SUMMARY OF THE INVENTION

Accordingly, the present invention is directed to a sampling system, that utilizes techniques for measuring replicated single-shot transient signals. Such a system generally includes: a single-shot transient signal acquisition and modulation unit; a gain-clamped regenerative delay line configured to produce a plurality of pulse replicas of a desired transient single-shot signal; and a timing means adapted for sampling the pulse replicas so as to substantially resolve and thus reproduce the signal.

Still another aspect of the present invention is directed to a sampling method that includes: providing a detected single-shot transient signal; regeneratively gain-clamp looping the detected single-shot transient signal to produce a plurality of pulse replicas of the transient single-shot signal; and sampling the pulse replicas to substantially reproduce a detected single-shot transient signal.

Accordingly, the present invention provides optical arrangements and methods that include a gain-clamped regenerative loop configuration to reproduce detected high bandwidth transient pulses generated by events such as, but not limited to, impulse radar, pulsed nuclear magnetic resonance, and shock physics.

### BRIEF DESCRIPTION OF THE DRAWINGS

The accompanying drawings, which are incorporated into and constitute a part of the specification, illustrate specific embodiments of the invention and, together with the general description of the invention given above, and the detailed description of the specific embodiments, serve to explain the principles of the invention.

FIG. 1 shows a simplified diagram of a regenerative gain-clamped transient single-shot sampling system.

FIG. 2 illustrates a plurality of reproduced pulses generated by the system of the present invention.

FIG. 3 shows another example embodiment of the regenerative gain-clamped delay line of the present invention.

### DETAILED DESCRIPTION OF THE INVENTION

Referring now to the drawings, specific embodiments of the invention are shown. The detailed description of the specific embodiments, together with the general description of the invention, serves to explain the principles of the invention.

General Description

The present invention provides a measurement system and method that includes a regenerative gain-clamped delay line for temporally measuring the shape of single-shot transient signals. A beneficial way of reproducing such signals is to use the optical portion of the electromagnetic spectrum in a converted electrical to optical signal gain-clamped fiber loop geometry to enable the reproduction of pulse shapes having a frequency of less than about 100 GHz with a resolution of down to about 4 ps.

A novel aspect of the present invention is the utilization of a doped fiber amplifier, such as, for example, an Erbium Doped Fiber Amplifier (EDFA) having a gain-clamped feedback loop. Such an arrangement entails an all-optical feedback lasing signal within a secondary loop, sustained by the amplifier itself, which clamps the average inversion and thus the gain for predetermined wavelengths to a desired level. By using such a design in the present invention, replica gain-clamped pulses can be surprisingly maintained with a signal to noise ratio of better than 10/1 for often up to about 1000 pulses within a primary optical loop so as to substantially reproduce a detected single-shot transient signal having a frequency of less than about 100 GHz with a resolution of down to about 4 ps.

Specific Description

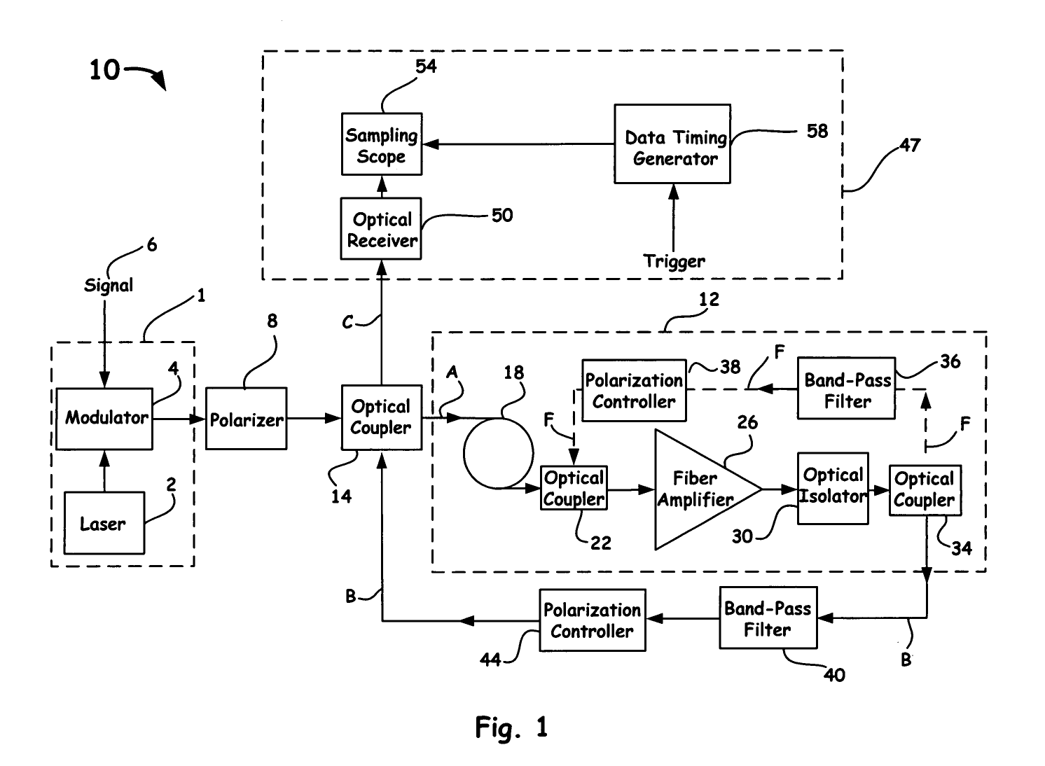

Turning now to the drawings, a diagram that illustrates an exemplary embodiment of a system constructed in accordance with the present invention is shown in FIG. 1. The system, designated generally by the reference numeral 10, and capable of being designed as a portable compact apparatus, generally includes a signal acquisition and modulation unit 1 (shown within a dashed rectangle), a gain-clamped regenerative delay line 12 (again shown within a dashed rectangle), and a timing means 47 (also shown within a dashed rectangle) for reproducing a detected single-shot transient signal.

Signal acquisition and modulation unit 1 is arranged to receive a single-pulse transient signal 6 and tracks such a received signal 6 by the induced modulation of an electromagnetic radiation beam traversing through an integrated-waveguide modulator 4, such as, for example, a LiNbO Mach-Zehnder modulator. The radiation source itself is often designed to be a laser 2 arranged to output up to about 60mW of optical power and capable of outputting a wavelength range between about 1310 nm and about 1550 nm, more often however, the output is designed about the low loss 1550 nm window for optical fibers. A beneficial arrangement is for laser 2 to be a narrow linewidth (e.g., 1 MHz) laser source, such as, a Distributed Feedback laser (DFB), having a limited chromatic dispersion-induced signal distortion of about 0.14 ps/km. Although a DFB is often a beneficial arrangement, other radiation sources, e.g., tunable single-longitudinal output optical sources, such as, but not limited to, Distributed Bragg Reflectors, Sampled Grating DBRs, Grating-assisted Co-directional Couplers with Sampled Reflectors, and Vertical Cavity Surface Emitting Lasers capable of operating within the designed parameters may also be utilized when operating within the scope and spirit of the present invention.

Turning back to FIG. 1 so as to describe the method and system of the invention, such a modulated output by signal acquisition and modulation unit 1, which is indicative of a detected single-pulse transient signal, is received by one or more optical elements, such as a polarizer 8 configured to restrict the vibration orientation of the output of laser 2. An optical coupler 14, such as, a 3 dB optical tap coupler, is configured to receive and direct such polarized components to gain-clamped regenerative delay line 12 (along a path denoted by the letter A).

Gain-clamped regenerative delay line 12 of the present invention generally includes a recirculating delay loop 18 and an amplifier 26, such as a Raman amplifier, more often a fiber amplifier, such as, an Erbium Doped Fiber Amplifier (EDFA) with a bandwidth of 5 tereahertz, and a noise figure of 3.5 dB. In addition regenerative delay line 12 includes a feedback loop (denoted by the letter F and shown as a dashed arrow path) for looping out and back to amplifier 26 a predetermined spectral bandwidth within the gain spectrum of amplifier 26 so as to deplete excited state ions and clamp the gain for a desired spectral bandwidth received from laser 2 (e.g., about 1550 nm).

Erbium-doped fiber amplifiers have an ultrafast (subfemtosecond) signal response, but also have a long excited state lifetime (10 ms). When a transient signal is injected into an EDFA, the excited state population is rapidly depleted. With the long excited state lifetime, recovery from this excited state depletion is slow, and the net result is the amplifier gain is greatly reduced. In transient sampling, this gain reduction results in signal reproductions with a rapidly decreasing amplitude. This reduced reproduction amplitude severely limits the number of samples and introduces significant signal distortion.

We have surprisingly discovered that gain clamping the EDFA in a transient sampling apparatus, as disclosed herein, results in constant amplitude signal replicas having a signal to noise ratio of better than 10/1, which, when sampled, result in accurate signal reconstructions. Without gain clamping, signal reproduction accuracy is severely limited.

Gain clamping is possible in an EDFA since the gain medium is homogeneously broadened, which means that excited state ions can participate in stimulated emission at different wavelengths. This is the key concept in gain clamping. The EDFA may be configured to lase on one wavelength, and amplify on another wavelength. In this configuration, excited state ions may be transferred from the lasing channel to the amplification channel instantaneously, compensating for changes in the amplifier gain due to the introduction of a fast transient signal pulse. The effect is to form an automatic gain control optical circuit.

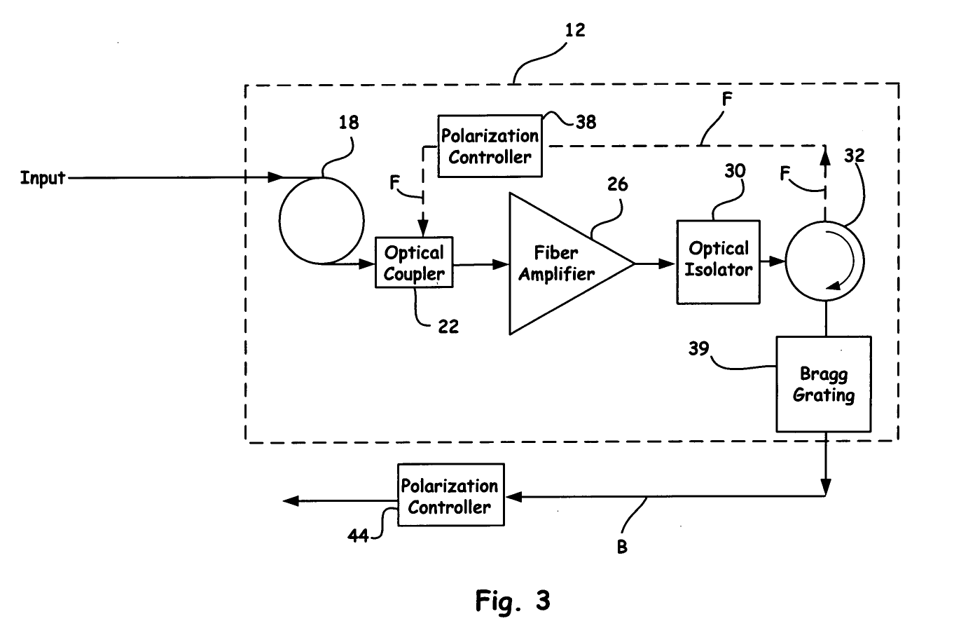

In FIG. 3, a train of reproduced signals in a gain clamped transient sampling device is shown. The original signal is pulse 92, as shown in FIG. 3, and a plurality of all the other pulses 96 are replicas of this original signal. Note that the amplitude of the signal reproductions is constant. In practice, several thousand signal reproductions, often up to about 1000 pulses with usable amplitudes, i.e., having a signal to noise ratio of better than 10/1, and minimal distortions can be produced. This allows a much higher effective sampling rate than in transient sampling devices that do not incorporate a gain clamp.

The signal is launched into gain-clamped regenerative delay line 12 (shown by path A) through, as one example configuration, a dispersion compensating (i.e., a fiber that includes positive dispersion (e.g., +18.5 ps/nm/km) and/or negative dispersion (e.g., −37 ps/nm/km)) low loss (i.e., about 0.2 dB) fiber arranged as recirculating delay loop 18. Delay loop 18 can be configured prior to amplifier 26 or such a delay loop 18 can be configured to follow amplifier 26 with design details implemented (e.g., integrating positive and/or negative dispersion fiber into the geometry in either configuration) to compensate for residual chromatic dispersion innduced when using such optical techniques and configurations. The use of this type of dispersion compensation is advantageous for transient sampling. Conventional zero dispersion fiber has large nonlinear susceptibilities that degrade the operation of transient sampling devices. Non-zero dispersion shifter fibers have reduced parasitic nonlinearities, but the residual chromatic dispersion limits the number of samples in a transient sampling device. The use of spliced negative and positive dispersion fibers in the loop results in zero dispersion with very low parasitic nonlinearities due to the significant dispersion in each segment of the fiber.

By arranging recirculating delay loop 18 to have predetermined lengths between about 5.5 km and 1.2 km, a time delay for pulses received from path B, as shown in FIG. 1, that traverses within such a loop, can enable state-of-the art sampling scope technologies having sampling rates between about 40 kHz and about 200 kHz to resolve single-shot transient pulses of less than about 100 GHz due to a plurality of generated and thus sampled replica pulses having a signal to noise ratio of better than 10/1.

After traversing through recirculating delay loop 18, such pulses can be directed to a second coupler 22, (e.g., a 3 dB tap coupler) which then can direct the pulses to amplifier 26. Amplifier 26, as stated herein before, is often an EDFA, which includes a fiber whose core is uniformly doped with Erbium ions to produce a homogeneously broadened simple two-level system. It is to be appreciated that the present invention capitalizes on such a system by configuring a feedback loop to induce a process known to those skilled in the art as cross-gain modulation, i.e., by directing a feedback signal to amplifier 26 of one wavelength (e.g., 1532 nm) so as to influence the gain for a desired signal wavelength (e.g., 1550 nm).

Generally, the feedback geometry, as shown in FIG. 1, can be arranged with an optical isolator 30 (to prevent reverse oscillations), a third optical coupler 34 to direct radiation along denoted paths F and/or B, a band-pass filter 36 for allowing only a predetermined feedback signal (e.g., 532 nm) to oscillate within feedback loop F, and a polarization controller 38 to restrict the polarization to a predetermined orientation so as to enable optical coupler 22 to direct the feedback signal in the polarization eigenstate of the loop, resulting in optimal amplitude for the signal reproductions.

Specifically, the feedback mechanism is in a fiber-loop geometry so as to effectively produce a ring laser. Such an optical feedback arrangement causes instability in the loop and if the gain in the fiber amplifier is initially greater than the loop loss, the fiber loop path starts oscillating at a wavelength determined by, for example, in-line band-pass filter 36 centered at a desired wavelength, e.g., at 1532 nm. The flux within the loop for such a lasing wavelength increases until its gain equals the loop loss, thus fixing (i.e., clamping) a desired inversion in the Erbium core of amplifier 26 and thus the gain for a predetermined wavelength (e.g., 1550 nm). Although the gain in such an arrangement is fixed, an alternate desired inversion, and thus the gain can be changed (e.g., for 1550 nm) by configuring system 10 to produce a different feedback wavelength within the homogenously broadened gain spectrum of amplifier 26 or by designing for increased gain or losses within the loop geometry utilizing optical components or techniques known to those skilled in the art.

Accordingly, a plurality of gain-clamped replica pulses of a detected. single-shot transient pulse is then directed along path B, as allowed by band-pass filter 40. Polarization controller 44 is arranged to produce a predetermined polarization for such pulses so as to enable optical coupler 14 to direct a produced optically split pulse of each of the replicated pulses to timing means 47 along path C, as shown in FIG. 1, and to direct a produced optically split pulse of each of the replicated pulses to gain-clamped regenerative delay line 12 along path A, as shown in FIG. 1, to repeat the process of producing replicas of a desired signal while retaining operation within the polarization eigenstate of the loops.

Timing means 47 (shown within a dashed rectangle) generally includes an optical receiver 50, such as, but not limited to, a Shottky or pin photodiode, to detect replicated pulses, a state-of-the-art sampling scope 54, and a Data Timing Generator 58 (shown having a received trigger pulse for timing purposes) to provide timing logic and reduce overall system jitter so as to optimize the number of pulses sampled by scope 54.

It is to be noted that although system 10, as shown in FIG. 1 has many types of undesired noise sources, such as, for example, scope noise (e.g., about 100 microwatts), modulator noise (e.g., about 50 microwatts), and EDFA noise of between about 25 to 900 microwatts. However, such noise is capable of being reduced in the present invention by replacing all fiber connections with fusion splices having, for example, a 0.3 dB loss, so that amplifier 26, (i.e., EDFA), as shown in FIG. 1, does not have to run as hard and so as to reduce overall system noise.

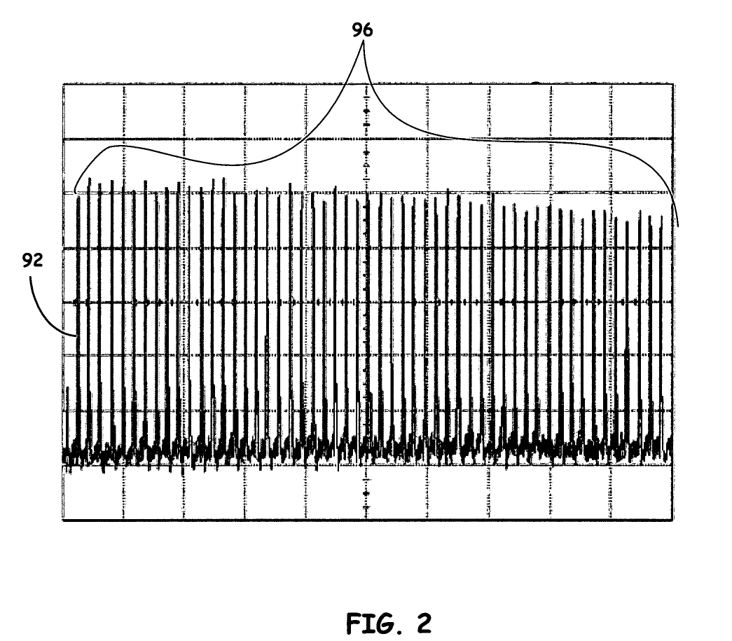

FIG. 3 shows another example embodiment of gain-clamped regenerative delay line 12, as shown in FIG. 1, having common optical components, i.e., recirculating delay loop 18, optical coupler 22, amplifier 26, optical isolator 30, and polarization controllers 38 and 44 operating as described above. However, in the example embodiment of FIG. 2, an output of amplifier 26 through optical isolator 30 is directed via an optical circulator 32 to an optical fiber grating 39, such as a Bragg grating, operating as a mirror for a predetermined wavelength (e.g., 532 nm). Upon reflection, optical circulator 32 can receive and direct such a predetermined wavelength to feedback loop F to fix the inversion of amplifier 26 as discussed above. Subsequently, gain clamped pulses having a desired wavelength (e.g., 1550 nm) are capable of being further directed by optical circulator 32 through fiber Bragg grating 39 (designed to be transmissive at such a wavelength) and along path B to be received by polarization controller 44 as discussed above in FIG. 1.

FIG. 2 illustrates a plurality of gain-clamped pulse replicas of a single-shot transient pulse as produced by the system and methods of the present invention. As shown in FIG. 3, a first pulse 92 is substantially replicated by a subsequent pulse 96 and a plurality of later pulses 98.

Applicants are providing this description, which includes drawings and examples of specific embodiments, to give a broad representation of the invention. Various changes and modifications within the spirit and scope of the invention will become apparent to those skilled in the art from this description and by practice of the invention. The scope of the invention is not intended to be limited to the particular forms disclosed and the invention covers all modifications, equivalents, and alternatives falling within the spirit and scope of the invention as defined by the claims.

1. A sampling system, comprising:
a single-shot transient signal acquisition and modulation unit;
a gain-clamped regenerative delay line, configured to produce a plurality of pulse replicas of said transient single-shot signal; and
timing means adapted for sampling said pulse replicas to substantially reproduce said single-shot transient signal.

2. The system of claim 1, wherein said plurality of pulse replicas comprises up to about 1000 pulses having a signal to noise ratio of better than 10/1.

3. The system of claim 1, wherein said gain-clamped regenerative delay line comprises an optical recirculating delay loop.

4. The system of claim 3, wherein said gain-clamped regenerative delay line comprises an optical-fiber amplifier.

5. The system of claim 4, wherein gain-clamping of said optical-fiber amplifier comprises a feedback loop adapted for redirecting a predetermined first spectral bandwidth to said optical amplifier so as to deplete excited state ions in said optical-fiber amplifier so as to clamp the gain for a predetermined second spectral bandwidth.

6. The system of claim 4, wherein said feedback loop further comprises a fiber Bragg grating adapted for reflecting said predetermined first spectral bandwidth.

7. The system of claim 4, wherein said feedback loop comprises a band-pass filter designed for said predetermined first spectral bandwidth.

8. The system of claim 7, wherein said feedback loop band-pass filter comprises a band-pass of about 1532 nm.

9. The system of claim 5, wherein said predetermined second spectral bandwidth is directed through a band-pass filter of about 1550 nm.

10. The system of claim 3, wherein said optical recirculating delay loop comprises a dispersion compensating fiber having a length between about 5.5 kilometers and about 1.2 kilometers.

11. The system of claim 4, wherein said optical-fiber amplifier comprises an Erbium-Doped Fiber Amplifier.

12. The system of claim 1, wherein said timing means comprises a sampling oscilloscope.

13. The system of claim 1, wherein said plurality of pulse replicas can be detected by a photoreceiver.

14. The system of claim 1, wherein said signal acquisition and modulation unit comprises a Mach-Zehnder modulator.

15. A sampling method, comprising:
providing a detected single-shot transient signal;
regeneratively gain-clamp looping said detected single-shot transient signal to produce a plurality of pulse replicas of said transient single-shot signal; and sampling said pulse replicas to substantially reproduce said single-shot transient signal.

16. The method of claim 15, wherein said regeneratively gain-clamp looping step comprises an optical recirculating delay line.

17. The method of claim 15, wherein said plurality of pulse replicas comprises up to about 1000 pulses having a signal to noise ratio of better than 10/1.

18. The method of claim 16, wherein said regeneratively gain-clamp looping step further comprises an optical-fiber amplifier.

19. The method of claim 18, wherein said regeneratively gain-clamp looping step comprises a feedback loop adapted for redirecting a predetermined first spectral bandwidth to said optical amplifier so as to deplete excited state ions in said optical-fiber amplifier so as to clamp the gain for a predetermined second spectral bandwidth.

20. The method of claim 19, wherein said feedback loop further comprises a fiber Bragg grating adapted to reflect said first predetermined spectral bandwidth.

21. The method of claim 19, wherein said feedback loop comprises a band-pass filter designed for said first predetermined spectral bandwidth.

22. The method of claim 21, wherein said feedback loop band-pass filter comprises a band-pass of about 1532 nm.

23. The method of claim 19, wherein said predetermined second spectral bandwidth comprises being directed through a band-pass filter of about 1550 nm.

24. The method of claim 16, wherein said optical recirculating delay line comprises a dispersion compensating fiber having a length between about 5.5 kilometers and about 1.2 kilometers.

25. The method of claim 18, wherein said optical-fiber amplifier comprises an Erbium-Doped Fiber Amplifier.

26. The method of claim 15, wherein said sampling step further comprises a sampling oscilloscope.

27. The method of claim 15, wherein said sampling step further comprises a data timing generator.

28. The method of claim 15, wherein said plurality of pulse replicas comprises being detected by a photoreceiver.

29. The method of claim 15, wherein said providing step comprises a Mach-Zehnder modulator.
